(19) United States
(12) Patent Application Publication
(10) Pub. No.: US 2026/0123168 A1
(43) Pub. Date: Apr. 30, 2026

(54) SOLAR BATTERY MODULE

(71) Applicant: KANEKA CORPORATION, Osaka (JP)

(72) Inventors: Kohei KOJIMA, Osaka (JP); Junichi NAKAMURA, Osaka (JP); Toru TERASHITA, Osaka (JP)

(73) Assignee: KANEKA CORPORATION, Osaka (JP)

(21) Appl. No.: 19/431,441

(22) Filed: Dec. 23, 2025

Related U.S. Application Data
(63) Continuation of application No. PCT/JP2024/023772, filed on Jul. 1, 2024.

(30) Foreign Application Priority Data
Jul. 3, 2023 (JP) 2023-109410

(51) Int. Cl. H10K 39/15; H10F 19/90; H10K 39/12; H10K 39/18

(52) U.S. Cl. CPC H10K 39/15; H10F 19/908; H10K 39/12; H10K 39/18

(57) ABSTRACT

A solar battery module which eliminates a difference in electromotive force of a solar battery cell on a rear side caused by a wiring material of a solar battery cell on a front side. The solar battery module comprises a first solar battery cell; a first current collector member that is connected to the first solar battery cell and is disposed on a rear side of the first solar battery cell; and a plurality of second solar battery cells that are disposed on a rear side of the first solar battery cell and the first current collector member and are different in absorption wavelength from the first solar battery cell. The second solar battery cell that overlaps the first current collector member in a plan view is exposed from the first solar battery cell in the plan view.

### CROSS-REFERENCE TO RELATED APPLICATIONS

This application claims benefit of priority to International Patent Application No. PCT/JP2024/023772, filed Jul. 1, 2024, and to Japanese Patent Application No. 2023-109410, filed Jul. 3, 2023, the entire contents of each are incorporated herein by reference.

### BACKGROUND

### Technical Field

The present disclosure relates to a solar cell module.

### Background Art

In order to improve photoelectric conversion efficiency of a solar cell module, a tandem type solar cell module in which two types of solar cells having different absorption wavelengths are arranged in an overlapping manner is known. A typical example is a solar cell module that includes a perovskite solar cell as a solar cell on the front side and a crystalline silicon solar cell as a solar cell on the back side, as described, for example, in PCT International Publication No. WO2019/087918.

### SUMMARY

The solar cells on the front and back sides are each connected to wiring materials for connecting the solar cells together and extracting power. In the case where a plurality of solar cells are arranged on each of the front and back sides, the wiring materials must be arranged also in the central portion of the solar cell module in plan view, and light incident on the solar cells on the back side is partially blocked. When the amount of incident light is different between the solar cells on the back side due to the light shielding by the wiring materials, there is a possibility that not only the output is lowered but also a current flows in the reverse direction inside the solar cells to cause loss and heat generation.

In view of such circumstances, the present disclosure provides a solar cell module in which the wiring material of the solar cells on the front side does not cause differences in electromotive force among the solar cells on the back side.

A solar cell module according to an aspect of the present disclosure includes a first solar cell, a first current collecting member connected to the first solar cell and disposed on a back side of the first solar cell, and a plurality of second solar cells disposed on a back side of the first solar cell and the first current collecting member and having an absorption wavelength different from that of the first solar cell. A second solar cell of the second solar cells that overlaps with the first current collecting member in plan view extends beyond the first solar cell in plan view.

In the solar cell module described above, at least two of the second solar cells may overlap with the first current collecting member. For each of the second solar cells that overlap with the first current collecting member, a ratio of an area where the second solar cell extends beyond the first solar cell and the first current collecting member to an area where the second solar cell overlaps with the first current collecting member may be substantially constant.

In the solar cell module described above, a plurality of the first solar cells may be arranged in a first direction with a gap therebetween. The first current collecting members may be laminated on both ends in the first direction of each of the first solar cells so as to extend in a second direction intersecting the first direction. At least one of the second solar cells may extend below the gap between the first solar cells.

In the solar cell module described above, the plurality of second solar cells may be connected in line in the first direction to form a solar cell string.

In the solar cell module described above, the second solar cells may be backside electrode type solar cells.

According to the present disclosure, it is possible to provide a solar cell module in which wiring materials of solar cells on the front side do not cause significant differences in electromotive force among solar cells on the back side.

### BRIEF DESCRIPTION OF THE DRAWINGS

FIG. 1 is a schematic plan view showing a solar cell module according to an embodiment of the present disclosure; and

FIG. 2 is a cross-sectional view of the solar cell module of FIG. 1 taken along line X-X.

### DETAILED DESCRIPTION

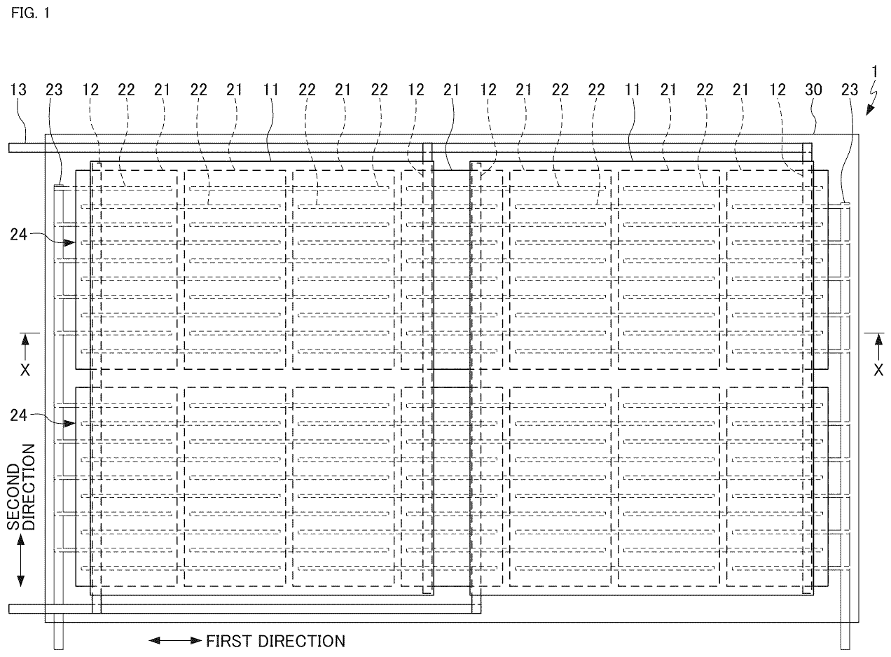

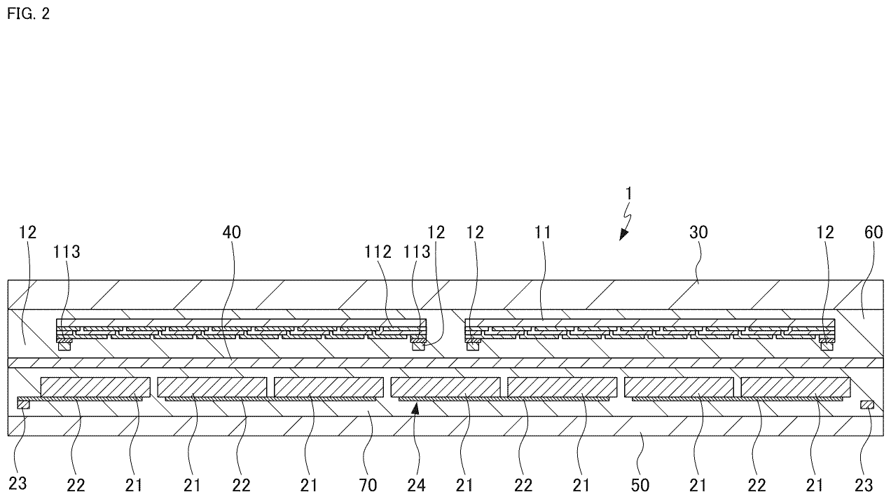

Hereinafter, an embodiment of the present disclosure will be described with reference to the drawings. The figure is a schematic plan view showing a solar cell module 1 according to an embodiment of the present disclosure. FIG. 2 is a cross-sectional view of the solar cell module 1 of FIG. 1 taken along line X-X.

The solar cell module 1 includes first solar cells 11, first current collecting members 12, first connection wiring materials 13, second solar cells 21, second current collecting members 22, second connection wiring materials 23, a front surface protection member 30, an insulating member 40, a back surface protection member 50, a first sealing material 60, and a second sealing material 70.

The first solar cell 11 is a photoelectric conversion device that absorbs light in a specific wavelength region and converts the light into power. In the illustrated embodiment, a plurality of (two) first solar cells 11 are arranged side by side with a gap therebetween in a first direction. The first solar cell 11 may be, for example, a perovskite solar cell including a photoelectric conversion layer containing a perovskite compound. The first solar cell 11 may be a submodule in which a plurality of subcells each independently performing photoelectric conversion are formed on a single substrate. In the illustrated embodiment, the first solar cells 11 are each formed in a band shape extending in a second direction intersecting the first direction, each includes a plurality of subcells arranged in the first direction, and each includes electrodes to which the first current collecting members 12 are connected on the outer sides in the first direction of the plurality of subcells, that is, on the back surfaces of both ends in the first direction.

The substrate of the first solar cell 11 is a plate-shaped or sheet-shaped structural member that ensures the strength of the first solar cell 11. The substrate may be formed of, for example, a resin such as polyimide, polyamide, or polyethylene terephthalate, or glass. The subcell may include a first transparent electrode layer, a photoelectric conversion layer, and a second transparent electrode layer in this order from the substrate side. The subcell may include further layers, such as a charge transport layer. The subcells may be formed in a state in which the subcells are separated from each other by a first separation groove that divides the first transparent electrode layer, a second separation groove that divides the photoelectric conversion layer in the vicinity of the first separation groove, and a third separation groove that divides the second transparent electrode layer in the vicinity of the second separation groove so that power can be extracted independently, and the subcells are electrically connected in series. The electrode to which the first current collecting member 12 is connected is connected to the first transparent electrode layer or the second transparent electrode layer of the adjacent subcell.

The first current collecting member 12 is connected to the first solar cell 11 and disposed on the back side of the first solar cell 11. The first current collecting member 12 is a member that extracts power from the first solar cell 11. Therefore, at least one pair of positive and negative first current collecting members 12 are connected to each first solar cell 11. More specifically, the first current collecting members 12 are respectively stacked on electrodes at both ends of the first solar cell 11 in the first direction, and extends in the second direction. The first current collecting member 12 is formed of a conductor such as copper in the shape of, for example, a wire, a strip, or a braided wire.

The first connection wiring material 13 is connected to the first current collecting members 12 of the corresponding same polarity connected to the first solar cells 11, and one end thereof extends outward from the space between the front surface protection member 30 and the insulating member 40. The first connection wiring material 13 is formed of, for example, the same material as that of the first current collecting member 12. The first connection wiring material 13 serves as connection wiring that electrically connects a plurality of first solar cells 11 and a lead-out line that outputs power to the outside of the solar cell module 1 from the connection body of the plurality of first solar cells 11.

The second solar cell 21 is disposed on the back side of the first solar cell 11 and the first current collecting member 12 via the insulating member 40. The absorption wavelength of the second solar cell 21 is different from that of the first solar cell 11. The second solar cell 21 may be, for example, a crystalline silicon solar cell including a crystalline silicon substrate that performs photoelectric conversion. In the illustrated embodiment, the second solar cells 21 are arranged in a matrix of seven rows in the first direction and two columns in the second direction. Seven second solar cells 21 aligned in a row in the second direction are electrically connected in series by the second current collecting members 22 to form a solar cell string 24. That is, the illustrated solar cell module 1 includes two solar cell strings 24. Since the second solar cells 21 can be positioned relatively accurately by using the solar cell string 24 in which the second solar cells 21 are connected, an effect of suppressing differences in electromotive force among the second solar cells 21 described later can be easily ensured.

The second solar cell 21 may have a configuration in which, for example, a first semiconductor layer and a second semiconductor layer having different polarities are stacked on a crystalline silicon substrate, and electrodes for collecting current are disposed on the semiconductor layers. The second solar cell 21 may be a double-sided electrode type solar cell in which electrodes are disposed on both sides, but is preferably a backside electrode type solar cell in which electrodes are disposed only on the back side. By using the backside electrode type solar cell, it is possible to more accurately estimate a change in the amount of light received by the second solar cell 21 due to the positional relationship with the first solar cell 11.

In the solar cell module 1, the plurality of second solar cells 21 all have the same size, but, in plan view, the second solar cells 21 overlap with the first solar cells 11 to differing degrees, and the second solar cells 21 overlap with the first current collecting members 12 to differing degrees. In the solar cell module 1 of the present embodiment, the second solar cells 21 at both ends in the first direction each overlap with one first current collecting member 12 in plan view, the second solar cells 21 at the center in the first direction each overlap with two first current collecting members 12 in plan view, and the other second solar cells 21 each overlap with no first current collecting member 12 in plan view. In the solar cell module 1 of the present embodiment, none of the second solar cells 21 overlap with the first connection wiring material 13 in plan view; however, it is also acceptable if part or all of the second solar cells 21 overlap with the first connection wiring material 13 in plan view.

The second solar cells 21 that overlap, in plan view, with the first current collecting member 12 extend beyond the first solar cell 11 in plan view. In the solar cell module 1 of the present embodiment, the second solar cells 21 at both ends in the first direction extend beyond the first solar cells 11 outward in the first direction, the second solar cells 21 at the center in the first direction extend below the gap between the first solar cells 11, and the other second solar cells 21 do not extend beyond the first solar cells 11. It is preferable that, for each of the second solar cells 21 that overlap with the first current collecting members 12, the ratio of the area where the second solar cell 21 extends beyond the first solar cell 11 to the area where the second solar cell 21 overlaps with the first current collecting member 12 is substantially constant. That is, the area (width in the first direction) where the second solar cell 21 extends beyond the first solar cell 11 is preferably substantially proportional to the area (width in the first direction) where the second solar cell 21 overlaps with the first current collecting member 12. By having part of the second solar cell 21 that overlaps with the first current collecting member 12 extend beyond the first solar cell 11, it is possible to compensate for a decrease in the amount of incident light due to light shielding of the first current collecting member 12 by an increase in the amount of incident light due to the second solar cell 21 extending beyond the first solar cell 11. Therefore, in the solar cell module 1, since no significant differences in electromotive force among the second solar cells 21 occur, it is possible to prevent a decrease in efficiency and heat generation due to differences in electromotive force among the second solar cells 21.

The first connection wiring material 13 is preferably disposed so as not to overlap with the second solar cells 21 in plan view. If the first connection wiring material 13 overlaps with the second solar cell 21 in plan view, it is preferable to set the area where the second solar cell 21 extends beyond the first solar cell 11 so as to offset light shielding caused by not only the first current collecting member 12 but also the first connection wiring material 13. In this case, the relationship between the area where the second solar cell 21 overlaps with the first current collecting member 12 and the first connection wiring material 13, and the area where the second solar cell 21 extends beyond the first solar cell 11 only needs to be substantially linear. As an example, the area of the first solar cell 11 can be made relatively large by providing an offset (intercept) such that the area where the second solar cell 21 extends beyond the first solar cell 11 is zero in the case where the area where the second solar cell 21 overlaps with the first current collecting member 12 and the first connection wiring material 13 is the smallest.

The second current collecting members 22 are connected to the second solar cells 21 and provide an electric path for extracting power from the second solar cells 21. In the solar cell module 1 of the present embodiment, the second current collecting members 22 electrically connect the second solar cells 21 in series in the first direction by connecting electrodes having different polarities of the adjacent second solar cells 21. The end on the outer side in the first direction of the second current collecting member 22 connected to the second solar cell 21 at the end of the solar cell string 24 is connected to the second connection wiring material 23.

The second connection wiring material 23 is connected to the second current collecting members 22, and the second connection wiring material 23 electrically connects the solar cell strings 24 in parallel. In addition, one end of the second connection wiring material 23 extends to the outside of the space between the back surface protection member 50 and the insulating member 40, and provides an electric path for outputting power from the connection body of the solar cell string 24 to the outside.

The front surface protection member 30 is a plate-shaped structural member that mainly defines the overall shape of the solar cell module 1. The front surface protection member 30 protects the first solar cells 11 and the second solar cells 21 by covering the front side of the first solar cells 11 via the first sealing material 60. The front surface protection member 30 preferably has excellent translucency, scratch resistance, and weather resistance. Examples of the material of the front surface protection member 30 include transparent resin such as acrylic resin and polycarbonate, and glass. In order to suppress reflection of light, the surface of the front surface protection member 30 may be processed into an uneven shape or may be covered with an antireflection coating layer.

The insulating member 40 covers the back side of the first solar cells 11, the first connection wiring material 13, and the first current collecting members 12, and prevents contact between them and the second solar cells 21. The insulating member 40 can be formed of a plate-shaped or sheet-shaped transparent material. Specifically, the insulating member 40 can be formed of, for example, a plate or a film of polyethylene terephthalate, polyethylene, a fluorine-containing resin, a silicone resin, glass, or the like.

The back surface protection member 50 is disposed on the back side of the second solar cells 21. The back surface protection member 50 protects the first solar cells 11 and the second solar cells 21 by covering the back surfaces of the second solar cells 21 via the first sealing material 60. The back surface protection member 50 can be formed of a plate-shaped or sheet-shaped material, and is preferably excellent in water barrier properties. Specifically, the back surface protection member 50 can be formed of, for example, a plate or a film of polyethylene terephthalate, polyethylene, a fluorine-containing resin, a silicone resin, glass, or the like, and a laminate of such a plate or film and a metal foil such as an aluminum foil may be used.

The first sealing material 60 is filled between the front surface protection member 30 and the insulating member 40, and seals the first solar cells 11 to protect them from moisture and the like. As the first sealing material 60, for example, a translucent resin such as an ethylene/vinyl acetate copolymer, an ethylene/α-olefin copolymer, ethylene/vinyl acetate/triallyl isocyanurate, polyvinyl butyrate, an acrylic resin, a urethane resin, or a silicone resin is preferably used. The first sealing material 60 is preferably formed of a material that has thermoplasticity to infiltrate into the gap between the first solar cells 11 during the manufacturing stage, and that loses its thermoplasticity in the final product, enabling it to maintain its shape even when the temperature of the solar cell module 1 rises. That is, the first sealing material 60 is preferably formed of a resin composition containing a thermoplastic resin as a main component, and a crosslinking agent that is activated at a temperature higher than the softening point of the thermoplastic resin and crosslinks and cures the thermoplastic resin.

The second sealing material 70 is filled between the insulating member 40 and the back surface protection member 50, and seals the second solar cells 21 to protect them from moisture and the like. The second sealing material 70 may be formed of the same material as the first sealing material 60.

As described above, in the solar cell module 1 of the present embodiment, the second solar cells 21 overlapping with the first current collecting members 12 in plan view extend beyond the first solar cells 11 in plan view, thereby compensating for a decrease in the amount of incident light due to the first current collecting members 12. Accordingly, in the solar cell module 1, since the electromotive force of each of the second solar cells 21 is substantially the same, it is possible to prevent a decrease in efficiency and heat generation due to imbalance in current among each of the second solar cells 21.

Although the embodiment of the present disclosure has been described above, the present disclosure is not limited to the above-described embodiment, and various modifications and variations can be made. In the solar cell module according to the present disclosure, the connection configuration of the first solar cells and the second solar cells may be freely changed. As an example, the first solar cells may be electrically connected in series.

What is claimed is:

1. A solar cell module comprising:
a first solar cell;
a first current collecting member connected to the first solar cell and disposed on a back side of the first solar cell; and
a plurality of second solar cells disposed on a back side of the first solar cell and the first current collecting member and having an absorption wavelength different from that of the first solar cell,
wherein at least one of the second solar cells overlaps with the first current collecting member in plan view and extends beyond the first solar cell in plan view.

2. The solar cell module according to claim 1, wherein
at least two of the second solar cells overlap with the first current collecting member, and
for each of the second solar cells that overlap with the first current collecting member, a ratio of an area where the second solar cell extends beyond the first solar cell and the first current collecting member to an area where the second solar cell overlaps with the first current collecting member is substantially constant.

3. The solar cell module according to claim 1, wherein
a plurality of the first solar cells are arranged in a first direction with a gap therebetween,
the first current collecting members are laminated on both ends in the first direction of each of the first solar cells so as to extend in a second direction intersecting the first direction, and
at least one of the second solar cells extends below the gap between the first solar cells.

4. The solar cell module according to claim 3, wherein
the plurality of second solar cells are connected in line in the first direction to configure a solar cell string.

5. The solar cell module according to claim 1, wherein
the second solar cells are backside electrode type solar cells.

6. The solar cell module according to claim 2, wherein
a plurality of the first solar cells are arranged in a first direction with a gap therebetween,
the first current collecting members are laminated on both ends in the first direction of each of the first solar cells so as to extend in a second direction intersecting the first direction, and
at least one of the second solar cells extends below the gap between the first solar cells.

7. The solar cell module according to claim 6, wherein
the plurality of second solar cells are connected in line in the first direction to configure a solar cell string.

8. The solar cell module according to claim 2, wherein
the second solar cells are backside electrode type solar cells.
